(19) United States
(12) Patent Application Publication
(10) Pub. No.: US 2010/0237742 A1
(43) Pub. Date: Sep. 23, 2010

(54) LAMB-WAVE RESONATOR AND OSCILLATOR

(75) Inventor: Satoru TANAKA, Chino-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 12/724,864

(22) Filed: Mar. 16, 2010

(30) Foreign Application Priority Data
Mar. 19, 2009 (JP) 2009-067545

(51) Int. Cl. H01L 41/04; H03B 5/32

(52) U.S. Cl. 310/313 D; 331/154

(57) ABSTRACT

A Lamb-wave resonator includes a piezoelectric substrate, and an IDT electrode disposed on one principal surface of the piezoelectric substrate. The IDT electrode has bus bar electrodes connecting sends of a plurality of electrode finger elements. The plurality of electrode finger elements being interdigitated with each other to form an apposition area. The IDT electrode includes a pair of reflectors disposed on the one principal surface of the piezoelectric substrate, and respectively arranged on both sides of the IDT electrode in a propagation direction of a Lamb wave.

### BACKGROUND

1. Technical Field

The present invention relates to a Lamb-wave resonator and an oscillator equipped with the Lamb wave resonator.

2. Related Art

A Lamb wave is a plate wave, which is a bulk wave propagating inside a substrate while being repeatedly reflected by upper and lower surfaces of the substrate in the case in which the substrate is arranged to have a thickness equal to or smaller than several wavelengths of the wave to be propagated. In contrast to a surface wave having 90% of the energy thereof in areas with a depth of within one wavelength from the surfaces of the substrate, such as a Rayleigh wave, a leaky surface acoustic wave, or a leaky surface-skimming compressional wave, the Lamb wave is a bulk wave propagating inside the substrate, and therefore, the energy thereof is distributed throughout the entire substrate.

According to “Ultrasonic Wave Handbook” edited by Ultrasonic Wave Handbook Editorial Committee, published by Maruzen Co., Ltd. in 1999, pp. 62-71, plate waves and Rayleigh waves are also distinguished academically. Further, in “Acoustic Wave Element Technical Handbook” edited by the 150th committee of the Nippon Academy Promotion Association, published by Ohmsha, Ltd. in 1991, pp. 148-158, there is disclosed a method for analyzing Rayleigh waves and leaky surface acoustic waves, and in “Temperature characteristics of the substrate for lamb wave type elastic wave devices” by Yasuhiko Nakagawa, Mitsuyoshi Shigeda, Kazumasa Shibata, and Shouji Kakio, IEICE Transactions on Electronics J-89C No. 1, pp. 34-39, there is disclosed a method for analyzing Lamb waves. As a big difference therebetween, there can be cited a difference in method of selecting the solution of the eighth equation between the waves, and therefore, Rayleigh waves and Lamb waves are completely different waves having properties different from each other. Therefore, since Lamb waves cannot provide favorable characteristics under design conditions the same as those of Rayleigh waves, a design approach specified for Lamb waves is required.

As a feature of Lamb waves, as shown in the dispersion curve disclosed in JP-A-2003-258596, a mode of Lamb waves, which can be propagated, is a mode in which a wave number in a thickness direction of a substrate satisfies resonance conditions, and Lamb waves have a number of modes including high order ones.

Since the phase velocity of the existing modes of Lamb waves is equal to or higher than that of Rayleigh waves, and many of the modes have a phase velocity equal to or higher than that of longitudinal waves, the higher the phase velocity of the mode is, the more easily the higher frequency can be achieved even in the case in which the width of the electrode fingers is the same as that in the case of the surface wave described above. Further, by using an AT cut quartz substrate having a thickness of 5 wavelengths or less, it becomes possible to use Lamb waves having an excellent temperature characteristic and suitable for achieving a high frequency.

According to JP-A-2003-258596 described above, there is described that metal having a higher specific gravity is used as an electrode, thereby making it possible to increase a reflection coefficient of Lamb waves, and to trap the energy with less number of reflectors, and therefore, downsizing becomes possible. This means that energy trapping is achieved by suppressing a vibration leakage in a lengthwise direction (a propagation direction of Lamb waves). However, it is hard to say that this electrode design is always optimum because energy trapping in a widthwise direction (a direction perpendicular to the propagation direction of Lamb waves) is not considered. Further, JP-A-2008-54163 also fails to disclose specific measures to enhance energy trapping in the widthwise direction.

If the vibration leakage occurs in the widthwise direction (a direction perpendicular to the propagation direction of the Lamb wave), it is possible that it is difficult to take full advantage of the preferable characteristic of the Lamb waves, and that degradation of the Q-value and increase in the CI-value, both the important factors in evaluating the resonance characteristic, are incurred. As a result, a sufficient characteristic is not obtained when applying it to an oscillator, and increase in power consumption and a serious problem of stoppage of oscillation are caused.

Further, if the vibration leakage in the widthwise direction reaches the widthwise outer end of the piezoelectric substrate, a spurious is caused by a reflected wave from the outer end of the piezoelectric substrate.

### SUMMARY

The invention is for solving at least a part of the problem described above, and can be realized as the following embodiments or aspects.

According to a first aspect of the invention, there is provided a Lamb-wave resonator including a piezoelectric substrate, an IDT electrode disposed on one principal surface of the piezoelectric substrate, having bus bar electrodes each connecting one ends of a plurality of electrode finger elements, the other ends of the plurality of electrode finger elements being interdigitated with each other to form an apposition area, and a pair of reflectors disposed on the one principal surface of the piezoelectric substrate, and respectively arranged on both sides of the IDT electrode in a propagation direction of a Lamb wave, wherein denoting a wavelength of the Lamb wave as λ, thickness t of the piezoelectric substrate satisfies 0<t/λ≦3, and defining that a value obtained by dividing electrode finger line width of the IDT electrode by λ/2 as a line width ratio, the line width ratio of each of the electrode finger elements in the apposition area as η_IDT, normalized electrode thickness obtained by normalization with the wavelength λ as H_IDT/λ, the line width ratio of the electrode finger elements in gap sections as areas between ends of the apposition area in a direction perpendicular to the propagation direction of the Lamb wave and the bus bar electrodes as η_g, and a normalized electrode thickness obtained by normalization with the wavelength λ as H_g/λ, each of H_IDT/λ, H_g/λ, η_IDT, and η_g is set so that a relationship between a frequency variation ΔF_IDT/F in the apposition area in a case of taking the frequency F with η_IDT=η_g=0 as a reference, and a frequency variation ΔF_g/F in the gap sections satisfies ΔF_IDT/F<ΔF_g/F. Furthermore, the ΔF_IDT/F is set a following equation,

$$Δ F \text{\_} IDT / F = ( 9.31535 \times {10}^{8} \times {( H \_ IDT / λ )}^{3} - 1.303219 \times {10}^{8} \times {( H\_IDT / λ )}^{2} + 1.707032 \times {10}^{6} \times ( H\_IDT / λ ) - 2.153813 \times {10}^{4} ) \times {η\_IDT}^{6} + ( - 2.265174 \times {10}^{9} \times {( H\_IDT / λ )}^{3} + 3.826626 \times {10}^{8} \times {( H\_IDT / λ )}^{2} - 5.666187 \times {10}^{6} \times ( H\_IDT / λ ) + 7.131896 \times {10}^{4} ) \times {η\_IDT}^{5} + ( 1.777402 \times {10}^{9} \times {( H\_IDT / λ )}^{3} - 4.02415 \times {10}^{8} \times {( H\_IDT / λ )}^{2} + 7.943602 \times {10}^{6} \times ( H\_IDT / λ ) - 9.161388 \times {10}^{4} ) \times {η\_IDT}^{4} + ( - 4.057486 \times {10}^{8} \times {( H\_IDT / λ )}^{3} + 1.792466 \times {10}^{8} \times {( H\_IDT / λ )}^{2} - 5.847306 \times {10}^{6} \times ( H\_IDT / λ ) + 5.720595 \times {10}^{4} ) \times {η\_IDT}^{3} + ( - 4.440021 \times {10}^{7} \times {( H\_IDT / λ )}^{3} - 2.971984 \times {10}^{7} \times {( H\_IDT / λ )}^{2} + 1.465112 \times {10}^{6} \times ( H\_IDT / λ ) - 1.766268 \times {10}^{4} ) \times {η\_IDT}^{2} + ( 5.803374 \times {10}^{6} \times {( H\_IDT / λ )}^{3} + 7.772027 \times {10}^{5} \times {( H\_IDT / λ )}^{2} - 4.721614 \times {10}^{4} \times ( H\_IDT / λ ) + 2.289947 \times {10}^{3} ) \times η\_IDT$$

in the case of satisfying the electrode line width ratio η≦1.0, the ΔF_g/F is set a following equation,

$$ΔF\_g / F = ( 2.30216 \times {10}^{8} \times {( H\_g / λ )}^{3} - 1.367095 \times {10}^{8} \times {( H\_g / λ )}^{2} + 3.659823 \times {10}^{6} \times ( H\_g / λ ) - 3.01777 \times {10}^{4} ) \times {η\_g}^{5} + ( - 5.380682 \times {10}^{9} \times {( H\_g / λ )}^{3} + 3.267274 \times {10}^{8} \times {( H\_g / λ )}^{2} - 8.220864 \times {10}^{6} \times ( H\_g / λ ) + 6.731244 \times {10}^{4} ) \times {η\_g}^{4} + ( 4.243229 \times {10}^{9} \times {( H\_g / λ )}^{3} - 2.672924 \times {10}^{8} \times {( H\_g / λ )}^{2} + 6.069945 \times {10}^{6} \times ( H\_g / λ ) - 4.768432 \times {10}^{4} ) \times {η\_g}^{3} + ( - 1.237277 \times {10}^{9} \times {( H\_g / λ )}^{3} + 8.270157 \times {10}^{7} \times {( H\_g / λ )}^{2} - 1.924936 \times {10}^{6} \times ( H\_g / λ ) + 9.760932 \times {10}^{3} ) \times {η\_g}^{2} + ( - 7.6659 \times {10}^{7} \times {( H\_g / λ )}^{3} - 6.447973 \times {10}^{6} \times {( H\_g / λ )}^{2} + 1.965583 \times {10}^{5} \times ( H\_g / λ ) + 9.0657 \times {10}^{2} ) \times η\_g$$

in the case of satisfying the electrode line width ratio η>1.0, the ΔF_g/F is set a following equation.

$$ΔF\_g / F = ( 9.77308 \times {10}^{7} \times {( H\_g / λ )}^{3} - 2.957309 \times {10}^{6} \times {( H\_g / λ )}^{2} + 3.402245 \times {10}^{5} \times ( H\_g / λ ) + 9.23408 \times {10}^{2} ) \times {η\_g}^{4} + ( - 5.997117 \times {10}^{8} \times {( H\_g / λ )}^{3} + 2.15036 \times {10}^{7} \times {( H\_g / λ )}^{2} - 2.052516 \times {10}^{6} \times ( H\_g / λ ) - 6.030188 \times {10}^{3} ) \times {η\_g}^{3} + ( 1.360087 \times {10}^{9} \times {( H\_g / λ )}^{3} - 5.537814 \times {10}^{7} \times {( H\_g / λ )}^{2} + 4.202198 \times {10}^{6} \times ( H\_g / λ ) + 1.459421 \times {10}^{4} ) \times {η\_g}^{2} + ( - 1.352976 \times {10}^{9} \times {( H\_g / λ )}^{3} + 6.122377 \times {10}^{7} \times {( H\_g / λ )}^{2} - 3.567924 \times {10}^{6} \times ( H\_g / λ ) - 1.553939 \times {10}^{4} ) \times η\_g + 4.989577 \times {10}^{8} \times {( H\_g / λ )}^{3} - 2.541272 \times {10}^{7} \times {( H\_g / λ )}^{2} + 8.585386 \times {10}^{5} \times ( H\_g / λ ) + 6.16996 \times {10}^{3}$$

Although the details will be explained in the embodiment described later, the following advantage can be obtained. The phase velocity of the Lamb wave has a property of depending on the normalized substrate thickness (t/λ), and rises as the normalized substrate thickness becomes smaller.

The Lamb-wave resonator has a plurality of modes, and the phase velocities in the respective modes aggregate in a range from 3000 (m/s) to 6000 (m/s), and in particular, densely aggregate in a range from 5000 (m/s) to 6000 (m/s), as the normalized substrate thickness t/λ increases.

It is conceivable that in the case in which the modes densely aggregate described as above, the mode coupling is apt to be caused, making it difficult to obtain a desired mode, or the phase velocity is apt to vary. Therefore, by setting the normalized substrate thickness to satisfy t/λ≦3, it becomes possible to eliminate the range in which the mode coupling is apt to occur.

Further, the relationship between the frequency variation ΔF_IDT/F in the apposition area and the frequency variation ΔF_g/F in the gap sections in the case of taking the frequency F corresponding to the condition of η_IDT=η_g=0 as a reference is set to be ΔF_IDT/F<ΔF_g/F. In other words, the phase velocity of the Lamb wave in the gap sections becomes higher than the phase velocity of the Lamb wave in the apposition area. Therefore, the displacement in the widthwise direction perpendicular to the propagation direction of the Lamb wave is converged in the areas outside the gap sections, thus the state with very little vibration leakage, namely the state in which the energy is trapped can be achieved.

As described above, by preventing the vibration leakage in the widthwise direction, it becomes possible to significantly reduce the amplitude of the reflected wave generated in the outer ends of the piezoelectric substrate in the widthwise direction, thereby reducing the spurious caused by the reflected waves from the outer ends of the piezoelectric substrate in the widthwise direction.

Further, by reducing the spurious caused by the reflected waves from the outer ends of the piezoelectric substrate in the widthwise direction, the drop of the O-value as an important factor in evaluating the resonance characteristic of the Lamb-wave resonator and the increase in the CI value are prevented. Therefore, the oscillation of the Lamb-wave resonator can stably be maintained with the high Q-value, and the reduction of the power consumption can be realized with the low CI value.

According to a second aspect of the invention, in the Lamb-wave resonator of the above aspect of the invention, it is preferable that the piezoelectric substrate is a quartz substrate having Euler angles (φ, θ, ψ) in ranges of −1°≦φ≦+1°, 35.0°≦θ≦47.2°, and −5°ψ≦5°, and a relationship between the thickness t and the wavelength λ of the Lamb wave satisfying 0.176≦t/λ≦1.925.

The frequency temperature characteristic, the frequency band, and the stability of the excitation of the Lamb-wave resonator are regulated by the cutout angle of the quartz substrate and the propagation direction of the acoustic wave. In other words, it is regulated by the angle θ of the Euler angles (0°, θ, 0°, and the normalized substrate thickness t/λ expressed by the relationship between the substrate thickness t and the wavelength λ.

By arranging the angle φ, the angle θ, the angle ψ, and the normalized substrate thickness t/λ to satisfy the relational expression described above, the frequency temperature characteristic superior to those of the STW-cut quartz device or the ST-cut quartz device, and support of a high-frequency band can be achieved.

Further, since the electromechanical coupling coefficient (K²) representing the efficiency of the excitation of the quartz substrate can be enhanced, it becomes possible to provide a Lamb-wave resonator easily excited and having a stable frequency temperature characteristic.

According to a third aspect of the invention, in the Lamb-wave resonator of the above aspect of the invention, it is preferable that the width of the apposition area of the electrode finger elements is equal to or larger than 20λ.

When considering an application to an oscillator, the Lamb-wave resonator cannot be applied to the oscillator unless the oscillation conditions in the combination with the oscillation circuit are satisfied. However, according to the measurement result of the admittance circle diagram in the vicinity of a resonant frequency described later in the embodiment, since the admittance B becomes to satisfy B<0 to provide conductivity providing the apposition width is equal to or larger than 20λ, stable oscillation can be achieved in the case of combining the Lamb-wave resonator and the oscillation circuit with each other.

According to a fourth aspect of the invention, in the Lamb-wave resonator of the above aspect of the invention, it is preferable that a relationship between a density ρ_IDT of the electrode finger elements in the apposition area and a density ρ_g of the electrode finger elements in the gap sections satisfies ρ_IDT>ρ_g.

It should be noted that as a material of the IDT electrode, for example, Al or a metal consisting primarily of Al can be used in the gap sections, and Cu, Ag, Au, or a metal consisting primarily of any of these materials can be used in the apposition area.

According to this aspect of the invention, it is possible to satisfy the condition of ΔF_IDT/F<ΔF_g/F similarly to the case of appropriately setting H_IDT/λ, H_g/λ, η_IDT, and η_g described above, and the state in which the displacement in the widthwise direction perpendicular to the propagation direction of the Lamb wave converges in areas outside the gap sections and very little vibration leakage occurs, namely the state in which the energy is trapped can be obtained.

According to a fifth aspect of the invention, in the Lamb-wave resonator of the above aspect of the invention, it is preferable that a film having an insulating property disposed on a surface of the electrode finger elements in the apposition area is further provided.

Here, as a material of the film having the insulating property, there can be adopted, for example, SiO₂, Si, SiₓN_{y}, Al₂O₃, ZnO, Ta₂O₅.

According to this aspect of the invention, the mass addition effect of the electrode finger elements in the apposition area and the gap sections become different from each other by disposing the film having an insulation property on the surface of the electrode finger elements in the apposition area. Therefore, it is possible to satisfy the condition of ΔF_IDT/F<ΔF_g/F similarly to the case of using metals different in density from each other in the apposition area and the gap sections of the electrode finger elements, respectively, and the state in which the displacement in the widthwise direction perpendicular to the propagation direction of the Lamb wave converges in areas outside the gap sections and very little vibration leakage occurs, namely the state in which the energy is trapped can be obtained.

According to a sixth aspect of the invention, there is provided an oscillator including the Lamb-wave resonator according to any one of the aspects of the invention described above, and an oscillation circuit adapted to excite the Lamb-wave resonator.

According to this aspect of the invention, by adopting the quartz substrate as the piezoelectric substrate, and adopting the Lamb-wave resonator having the optimum substrate thickness and the optimum configuration of the IDT electrode described above to thereby prevent the vibration leakage in the widthwise direction, thus it becomes possible to provide an oscillator with a high Q-value and a low CI value, and superior in frequency temperature characteristic.

### BRIEF DESCRIPTION OF THE DRAWINGS

The invention will now be described with reference to the accompanying drawings, wherein like numbers reference like elements.

FIG. 1 is a diagram showing an azimuth direction in which a quartz substrate is cut out and a direction in which a Lamb wave propagates according to an embodiment.

FIGS. 2A and 2B are diagrams showing a basic form of a Lamb-wave resonator according to the embodiment, wherein FIG. 2A is a perspective view showing a schematic structure thereof, and FIG. 2B is a cross-sectional view showing a cutting surface along the line A-A in FIG. 2A.

FIG. 3 is a graph showing a relationship between the normalized substrate thickness t/λ and the phase velocity.

FIGS. 4A and 4B are diagrams showing an example of the Lamb-wave resonator, wherein FIG. 4A is a plan view thereof viewed from a principal surface thereof, and FIG. 4B is a cross-sectional view showing a cutting surface along the line B-B in FIG. 4A.

FIG. 5 is a graph showing a relationship between an electrode line width ratio normalized electrode thickness at each region of an electrode finger element, and a frequency shift (ppm).

FIG. 6 is a graph showing a change in a Q-value corresponding to a change in a line width ratio η_g in gap sections in the case in which a line width ratio η_IDT in an apposition area of the electrode finger element is set to be 0.5.

FIG. 7 is a graph showing a change in a Q-value corresponding to a change in a line width ratio η_g in gap sections in the case in which a line width ratio η_IDT in an apposition area of the electrode finger element is set to be 0.8.

FIG. 8 is a graph showing a relationship between a frequency temperature variation (ppm) and an angle θ of Euler angles (0°, θ, 0°).

FIG. 9 is a graph showing a relationship between the frequency temperature variation (ppm) and the normalized substrate thickness t/A.

FIG. 10 is a graph showing a relationship between the angle θ in the Euler angles (0°, ƒ, 0° and a phase velocity.

FIG. 11 is a graph showing a relationship between the normalized substrate thickness t/λ and the phase velocity.

FIG. 12 is a graph showing relationships between the angle θ, and the phase velocity and the frequency temperature variation.

FIG. 13 is a graph showing relationships between the angle θ, and an electromechanical coupling coefficient K² and the frequency temperature variation.

FIG. 14 is a graph showing relationships between the normalized substrate thickness t/λ, and the phase velocity and the frequency temperature variation.

FIG. 15 is a graph showing relationships between the normalized substrate thickness t/λ and the electromechanical coupling coefficient K² and the frequency temperature variation.

FIG. 16 is a graph showing a relationship between the electrode line width ratio η and a frequency variation (described as a frequency shift) in the case in which Al, Cu, Ag, or Au is used in the apposition area, and Al is used in the gap sections.

FIG. 17 is a plan view showing a schematic configuration of the Lamb-wave resonator according to Example 3.

FIG. 18 is an admittance circle diagram in the vicinity of a resonant frequency.

### DESCRIPTION OF AN EXEMPLARY EMBODIMENT

An embodiment of the invention will hereinafter be explained with reference to the accompanying drawings.

It should be noted that the drawings referred to in the following explanations are schematic diagrams having contraction scales in the vertical and horizontal directions of the members or parts different from the actual scales for the sake of convenience of illustration.

### Embodiment

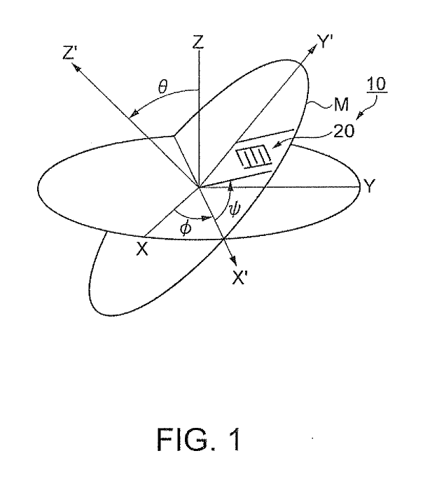

FIG. 1 is an explanatory diagram showing an azimuth direction in which a quartz substrate is cut out and a direction in which a Lamb wave propagates according to the present embodiment, namely an explanatory diagram of the Euler angles (φ, θ, ψ). The azimuth direction in which the quartz substrate 10 as a piezoelectric substrate is cut out is defined by an X axis called an electrical axis, a Y axis called a mechanical axis, and a Z axis called an optical axis.

The quartz substrate 10 expressed by the Euler angles (0°, 0°, 0°) forms a Z-cut substrate having a main surface perpendicular to the Z axis. Here, the angle φ in the Euler angles relates to a first rotation of the Z-cut substrate, and represents a first rotation angle assuming that the Z axis is a rotation axis, and the rotation direction in a rotational direction from +X axis to +Y axis is a positive rotation angle.

The angle θ of the Euler angles relates to a second rotation performed subsequently to the first rotation of the Z-cut substrate, and represents a second rotation angle assuming that the X axis after the first rotation has been performed is the rotation axis, and the rotation angle in a rotational direction from +Y axis to +Z axis after the first rotation has been performed is a positive rotation angle. A cut surface of the quartz substrate 10 is determined based on the first rotation angle and the second rotation angle θ.

The angle ψ of the Euler angles relates to a third rotation performed subsequently to the second rotation of the Z-cut substrate, and represents a third rotation angle assuming that the Z axis after the second rotation has been performed is the rotation axis, and the rotation angle in a rotational direction from +X axis to +Y axis after the second rotation has been performed is a positive rotation angle. The propagation direction of the Lamb wave is represented by the third rotation angle ψ with respect to the X axis after the second rotation has been performed.

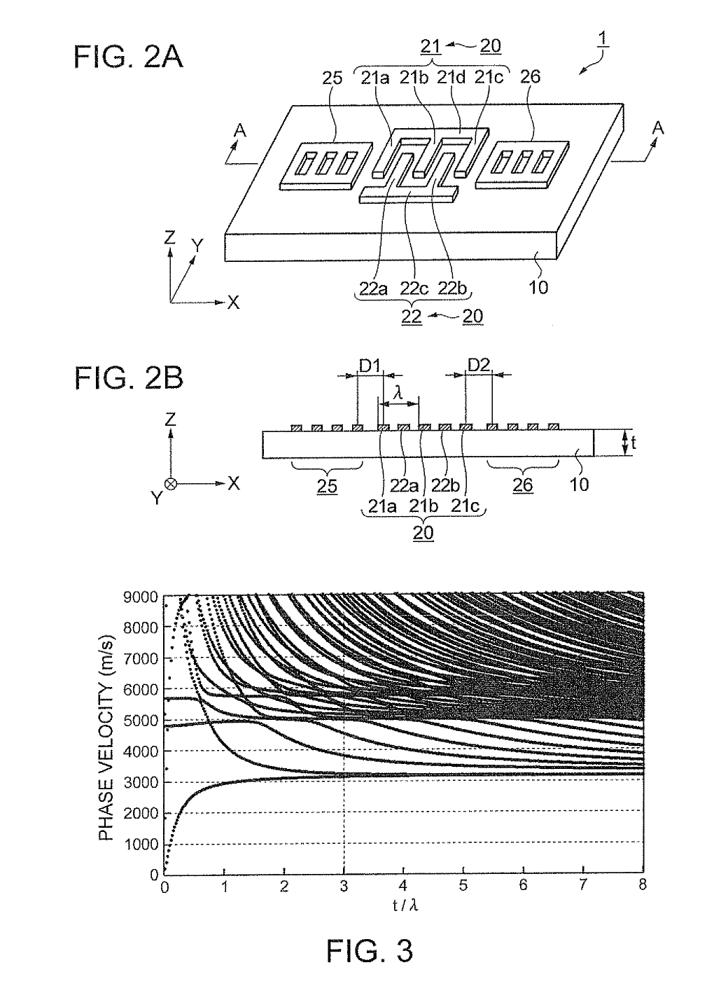

FIGS. 2A and 2B are diagrams showing a basic form of a Lamb-wave resonator according to the embodiment, wherein FIG. 2A is a perspective view showing a schematic structure thereof, and FIG. 23 is a cross-sectional view showing a cutting surface along the line A-A in FIG. 2A. The quartz substrate 10 according to the present embodiment is a rotated Y-cut quartz substrate having the cutout direction in which the Z axis in a thickness direction is rotated up to Z′ by the angle θ, and is cut out so that the longitudinal direction corresponds to the X axis, the width direction corresponds to Y′, and the thickness direction corresponds to Z′ in the drawing (see FIG. 1).

In FIGS. 2A and 23, a Lamb-wave resonator 1 includes the quartz substrate 10, an interdigital transducer (IDT) electrode 20 formed in an X-axis direction on one of main surfaces of the quartz substrate 10 so as to have a comb-tooth shape, a pair of reflectors 25 and 26 formed on both sides of the IDT electrode 20 in the propagation direction of the Lamb wave. Therefore, the propagation direction of the Lamb wave is set to be the X-axis direction.

Further, assuming that the thickness of the quartz substrate 10 is t, and the wavelength of the Lamb wave to be propagated is λ, a normalized substrate thickness t/λ is set to be in a range expressed by 0<t/λ≦3.

The IDT electrode 20 is formed of Al electrodes, and is composed of an input IDT electrode 21 and a ground (GND) IDT electrode 22. The ground (GND) IDT electrode 22 is not necessarily required to be grounded, but can be connected to a signal line. The input IDT electrode 21 has a plurality of electrode finger elements 21a, 21b, and 21c formed to have the same length and arranged to be parallel to each other, wherein one ends of the electrode finger elements 21a, 21b, and 21c are connected to each other via a bus bar electrode 21d. The GND IDT electrode 22 has a plurality of electrode finger elements 22a and 22b formed to have the same length and arranged to be parallel to each other, wherein one ends of the electrode finger elements 22a and 22b are connected to each other via a bus bar electrode 22c.

Tip portions of the electrode finger elements of the input IDT electrode 21 and the GND IDT electrode 22 are interdigitated to each other. The tip portions of the electrode finger elements 21a, 21b, and 21c are each disposed so as to have a space with the bus bar electrode 22c. Further, the tip portions of the electrode finger elements 22a and 22b are each disposed so as to have a space with the bus bar electrode 21d.

It should be noted that the width of the portions of the electrode finger elements 21a, 21b, and 21c of the input IDT electrode 21 and electrode finger elements 22a and 22b of the GND IDT electrode 22 opposed to each other when the electrode finger elements of the input IDT electrode 21 and the electrode finger elements of the GND IDT electrode 22 are interdigitated to each other is described as an apposition width.

It should be noted that in FIGS. 2A and 2B, the electrode finger elements of the IDT electrode 20 and the reflectors 25 and 26 are schematically illustrated with respect to the numbers thereof, and in practice, several tens through several hundreds of electrode finger elements are provided respectively.

The quartz substrate 10 is a thin plate having surfaces in the directions of the X axis called the electrical axis, the Y axis called the mechanical axis, and the Z axis called the optical axis. However, the quartz substrate 10 according to the present embodiment is the rotated Y-cut quartz substrate having the cutout direction in which the Z axis in the thickness direction is rotated up to Z′ by the angle θ, and in FIGS. 2A and 2B, the axis directions of the quartz substrate 10 shown in the drawing are indicated. Therefore, the thickness direction is represented as Z, the propagation direction of the Lamb wave is represented as λ, and a direction perpendicular to the propagation direction of the Lamb wave is represented as Y. It should be noted that the X direction might be described as a lengthwise direction, and the Y direction might be described as a widthwise direction.

In the present embodiment, it is arranged that the pitch of the electrode finger elements 21a, 21b, and 210 and the pitch of the electrode finger elements 22a and 22b are λ (the wavelength of the Lamb wave), and the width of each of the electrode finger elements and the distance between the electrode finger elements adjacent to each other are (¼)λ.

In the Lamb-wave resonator 1, the quartz substrate 10 is excited by a drive signal input to the input IDT electrode 21 at a predetermined frequency, wherein the acoustic wave thus excited propagates towards the X direction of the quartz substrate 10 while being reflected by the top and bottom surfaces of the quartz substrate 10. The acoustic wave propagating as described above is called a Lamb wave.

Although the structure of the IDT electrode 20 is similar to that of an SAW resonator, the characteristic thereof is different therefrom because of the difference in the type of waves to be used therein, and therefore, the design conditions are naturally different therefrom. Then, the Lamb wave propagating from the IDT electrode 20 is reflected by the reflectors 25 and 26.

Accordingly, the distance D1 from the center of the electrode finger element 21a in the propagation direction of the Lamb wave to the center of the closest one of the electrode finger elements of the reflector 25 to the electrode finger element 21a in the propagation direction of the Lamb wave, and the distance D2 similarly from the center of the electrode finger element 21c in the propagation direction of the Lamb wave to the center of the closest one of the electrode finger elements of the reflector 26 to the electrode finger element 21c in the propagation direction of the Lamb wave are set to be (½) (“n” is an integer) so that the reflected waves have the phases identical to that of the drive signal at a predetermined frequency.

It should be noted that it is possible to set the distance D1 between the electrode finger element 21a and the reflector 25 and the distance D2 between the electrode finger element 21c and the reflector 26 to be different from (½)λ.

Subsequently, the relationship between the normalized substrate thickness t/λ and the phase velocity will be explained with reference to the accompanying drawings.

FIG. 3 is a graph showing the relationship between the normalized substrate thickness t/λ and the phase velocity. The horizontal axis represents the normalized substrate thickness t/λ, and the vertical axis represents the phase velocity (m/s). Further, the Lamb-wave resonator employing the quartz substrate 10 as a piezoelectric substrate is shown as an example.

According to FIG. 3, there is shown the fact that the Lamb-wave resonator 1 has a plurality of modes, and that the phase velocities in the respective modes aggregate in a range from 3000 (m/s) to 6000 (m/s), and in particular, densely aggregate in a range from 5000 (m/s) to 6000 (m/s), as the normalized substrate thickness t/λ increases.

It is conceivable that in the case in which the modes densely aggregate described as above, the mode coupling is apt to be caused, making it difficult to obtain a desired mode, or the phase velocity is apt to vary. Therefore, by setting the normalized substrate thickness to satisfy t/λ≦3, it becomes possible to eliminate the range in which the mode coupling is apt to occur.

Further, according to FIG. 3, there is shown a tendency that the smaller the normalized substrate thickness t/λ is, the higher the phase velocity becomes, and in the range of the normalized substrate thickness t/λ satisfying t/λ≦3, there exist a number of modes having the phase velocity of equal to or higher than 6000 (m/s). Since the phase velocity is represented by a product of a frequency and a wavelength, this shows that the Lamb-wave resonator is available for a high frequency application.

Regarding the Lamb-wave resonators, although there are some documents related to basic properties thereof, no document related to the energy trapping in the widthwise direction (the Y direction) can be found, and therefore, the optimum design conditions remain unclear. Therefore, the inventors have proceeded with a detailed investigation related to the energy trapping of the Lamb wave in the widthwise direction.

As a result, it has turned up that Lamb waves are apt to cause the vibration leakage in the widthwise direction compared to quartz SAW, and are sensitive to the design conditions of the apposition width Wi and the gap Wg of the electrode finger elements, and therefore, it is effective for trapping the energy in the widthwise direction to set the phase velocity in the range of the apposition width Wi to be lower than the phase velocity in the range of the gap Wg.

Then, a differential equation controlling a displacement of the Lamb wave in the widthwise (Y) direction will be described. This differential equation can be obtained based on Lagrangian L=T−U (T represents kinetic energy, and U represents potential energy), which can be obtained by integrating the vibration energy of the Lamb-wave resonator in length and depth directions, and can be expressed as the following formula.

$$a {ω}_{0}^{2} \frac{{\partial }^{2} U ( Y )}{\partial {Y}^{2}} + ( {ω}^{2} - {ω}_{0}^{2} ) U ( Y ) = 0 \qquad ( 1 )$$

Here, U(Y) represents a widthwise displacement, Y represents a y coordinate (y/λ) normalized by the wavelength λ of the Lamb wave, a constant “a” represents a shear effect coefficient in the widthwise direction, ω represents an angular frequency, ωₒ represents an angular frequency of the Lamb-wave resonator with the electrode finger elements having the infinite apposition width. The constant “a” is obtained based on an analysis result, or a measurement result, and is 0.021 in the embodiment. Based on the differential equation, the displacement of the Lamb-wave resonator in the widthwise direction is calculated.

Subsequently, some specific working examples will be explained with reference to the drawings.

### Example 1

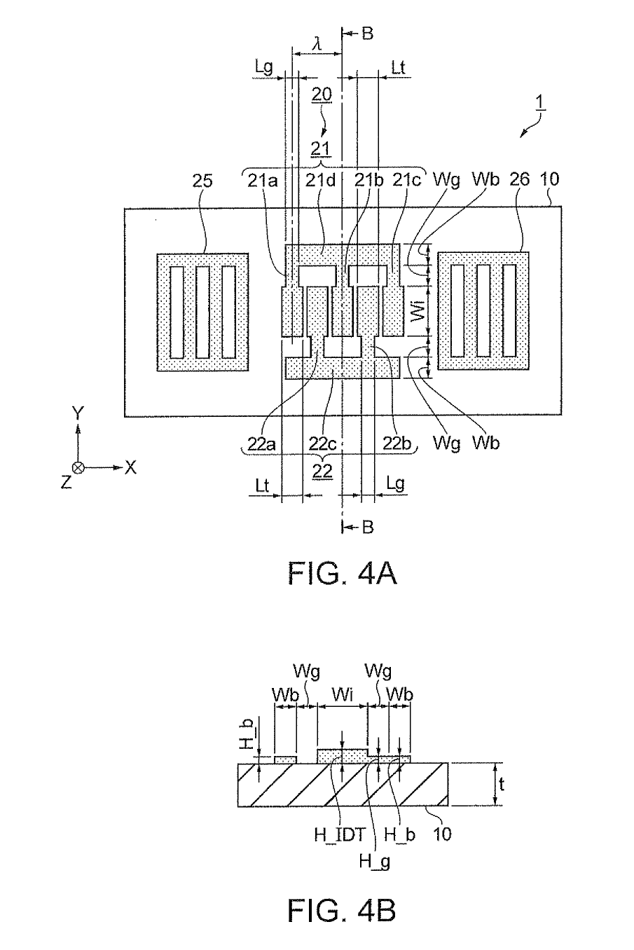

FIGS. 4A and 4B are diagrams showing an example of the Lamb-wave resonator, wherein FIG. 4A is a plan view thereof viewed from a principal surface thereof, and FIG. 4B is a cross-sectional view showing a cutting surface along the line B-B in FIG. 4A. Firstly, optimum electrode design parameters proposed in the present working example will be explained.

In FIG. 4A, the electrode finger line width Lt (hereinafter also referred to simply as a line width) of each of the electrode finger elements 21a, 21b, 21c, 22a, and 22b in the apposition section where the electrode finger elements 21a, 21b, and 21c and the electrode finger elements 22a and 22b are interdigitated with each other is formed to be larger than the electrode finger line width Lg thereof in the gap sections.

Here, it is assumed that the value obtained by dividing the electrode finger line width of the IDT electrode 20 by λ/2 is a line width ratio, the line width ratio of each of the electrode finger elements in the apposition area is η_IDT, the line width ratio of the electrode finger element in areas (hereinafter described as gap sections) between the respective ends of the apposition area in a direction (the Y direction) perpendicular to the propagation direction (the X direction) of the Lamb wave and the bus bar electrodes 21d, 22c is η_g, and the pitch of each of the electrode finger elements 21a, 21b, and 21c, and the electrode finger elements 22a and 22b is λ. Therefore, the pitch between the electrode finger element 21a and the electrode finger element 22a is (½)λ.

Further, the width of the apposition area of the electrode finger elements is denoted as Wi, the width (the distance) of the gap sections is denoted as Wg, and the width of each of the bus bar electrodes is denoted as Wb.

It should be noted that since the relationships between the reflectors 25, 26 and the IDT electrode 20 are set to be substantially the same as shown in FIGS. 2A and 2B described above, the explanations therefor will be omitted. Further, the normalized substrate thickness t/λ of the quartz substrate 10 is set within the range of 0<t/λ≦3.

Then, the cross-sectional configuration of the Lamb-wave resonator 1 will be explained with reference to FIG. 4B. The thickness of the apposition section (the range of the apposition width Wi) of the electrode finger elements is denoted as H_IDT, the thickness of the gap sections (the range of the distance Wg) is denoted as H_g, normalized electrode thickness obtained by the normalization with the wavelength λ is denoted as H_IDT/λ, the thickness of the bus bar electrodes (the ranges of the width Wb) is denoted as H_b, and normalized electrode thickness obtained by the normalization with the wavelength λ is denoted as H_g/λ. It should be noted that the thickness of the gap sections and the thickness of the bus bar electrodes are set so as to satisfy H_g=H_b.

Subsequently, a relationship between the electrode line width ratio η and the frequency variation (referred to as the frequency shift in some cases) will be explained. Here, taking the frequency of the case satisfying η_IDT=η_g=0 as a reference, denoting the frequency in the apposition area as F_IDT, the frequency of the gap sections as F_g, the frequency shifts thereof as ΔF_IDT/F and ΔF_g/F, respectively, and the frequency shift will be analyzed using the following calculating formula. Firstly, the calculation formula for obtaining the frequency shift ΔF_IDT/F of the apposition area will be shown in formula (2).

Further, in the present embodiment, the calculation is performed assuming the Euler angles (0°, 42°, 0°) and the normalized substrate thickness t/λ=1.6.

$$ΔF\_IDT / F = ( 9.31535 \times {10}^{8} \times {( H\_IDT / λ )}^{3} - 1.303219 \times {10}^{8} \times {( H\_IDT / λ )}^{2} + 1.707032 \times {10}^{6} \times ( H\_IDT / λ ) - 2.153813 \times {10}^{4} \times {η\_IDT}^{6} + ( - 2.265174 \times {10}^{9} \times {( H\_IDT / λ )}^{3} + 3.826626 \times {10}^{8} \times {( H\_IDT / λ )}^{2} - 5.666187 \times {10}^{6} \times ( H\_IDT / λ ) + 7.131896 \times {10}^{4} ) \times {η\_IDT}^{5} + ( 1.777402 \times {10}^{9} \times {( H\_IDT / λ )}^{3} - 4.02415 \times {10}^{8} \times {( H\_IDT / λ )}^{2} + 7.943602 \times {10}^{6} \times ( H\_IDT / λ ) - 9.161388 \times {10}^{4} ) \times {η\_IDT}^{4} + ( - 4.057486 \times {10}^{8} \times {( H\_IDT / λ )}^{3} + 1.792466 \times {10}^{8} \times {( H\_IDT / λ )}^{2} - 5.847306 \times {10}^{6} \times ( H\_IDT / λ ) + 5.720595 \times {10}^{4} ) \times {η\_IDT}^{3} + ( - 4.440021 \times {10}^{7} \times {( H\_IDT / λ )}^{3} - 2.971984 \times {10}^{7} \times {( H\_IDT / λ )}^{2} + 1.465112 \times {10}^{6} \times ( H\_IDT / λ ) - 1.766268 \times {10}^{4} ) \times {η\_IDT}^{2} + ( 5.803374 \times {10}^{6} \times {( H\_IDT / λ )}^{3} + 7.772027 \times {10}^{5} \times {( H\_IDT / λ )}^{2} - 4.721614 \times {10}^{4} \times ( H\_IDT / λ ) + 2.289947 \times {10}^{3} ) \times η\_IDT \qquad ( 2 )$$

Then, the calculating formula for obtaining the frequency shift ΔF_g/F of the gap sections in the case of satisfying the electrode line width ratio η≦1.0 is shown in formula (3).

$$ΔF\_g / F = ( 2.30216 \times {10}^{8} \times {( H\_g / λ )}^{3} - 1.367095 \times {10}^{8} \times {( H\_g / λ )}^{2} + 3.659823 \times {10}^{6} \times ( H\_g / λ ) - 3.01777 \times {10}^{4} ) \times {η\_g}^{5} + ( - 5.380682 \times {10}^{9} \times {( H\_g / λ )}^{3} + 3.267274 \times {10}^{8} \times {( H\_g / λ )}^{2} - 8.220864 \times {10}^{6} \times ( H\_g / λ ) + 6.731244 \times {10}^{4} ) \times {η\_g}^{4} + ( 4.243229 \times {10}^{9} \times {( H\_g / λ )}^{3} - 2.672924 \times {10}^{8} \times {( H\_g / λ )}^{2} + 6.069945 \times {10}^{6} \times ( H\_g / λ ) - 4.768432 \times {10}^{4} ) \times {η\_g}^{3} + ( - 1.237277 \times {10}^{9} \times {( H\_g / λ )}^{3} + 8.270157 \times {10}^{7} \times {( H\_g / λ )}^{2} - 1.924936 \times {10}^{6} \times ( H\_g / λ ) + 9.760932 \times {10}^{3} ) \times {η\_g}^{2} + ( - 7.6659 \times {10}^{7} \times {( H\_g / λ )}^{3} - 6.447973 \times {10}^{6} \times {( H\_g / λ )}^{2} + 1.965583 \times {10}^{5} \times ( H\_g / λ ) + 9.0657 \times {10}^{2} ) \times η\_g \qquad ( 3 )$$

Then, the calculating formula for obtaining the frequency shift ΔF_g/F of the gap sections in the case of satisfying the electrode line width ratio η>1.0 is shown in formula (4).

$$ΔF\_g / F = ( 9.77308 \times {10}^{7} \times {( H\_g / λ )}^{3} - 2.957309 \times {10}^{6} \times {( H\_g / λ )}^{2} + 3.402245 \times {10}^{6} \times ( H\_g / λ ) + 9.23408 \times {10}^{2} ) \times {η\_g}^{4} + ( - 5.997117 \times {10}^{8} \times {( H\_g / λ )}^{3} + 2.15036 \times {10}^{7} \times {( H\_g / λ )}^{2} - 2.052516 \times {10}^{6} \times ( H\_g / λ ) - 6.030188 \times {10}^{3} ) \times {η\_g}^{3} + ( 1.360087 \times {10}^{9} \times {( H\_g / λ )}^{3} - 5.537814 \times {10}^{7} \times {( H\_g / λ )}^{2} + 4.202198 \times {10}^{6} \times ( H\_g / λ ) + 1.459421 \times {10}^{4} ) \times {η\_g}^{2} + ( - 1.352976 \times {10}^{9} \times {( H\_g / λ )}^{3} + 6.122377 \times {10}^{7} \times {( H\_g / λ )}^{2} - 3.567924 \times {10}^{6} \times ( H\_g / λ ) - 1.553939 \times {10}^{4} ) \times η\_g + 4.989577 \times {10}^{8} \times {( H\_g / λ )}^{3} - 2.541272 \times {10}^{7} \times {( H\_g / λ )}^{2} + 8.585386 \times {10}^{5} \times ( H\_g / λ ) + 6.16996 \times {10}^{3} \qquad ( 4 )$$

Subsequently, the analysis result obtained by the formulas described above will be explained.

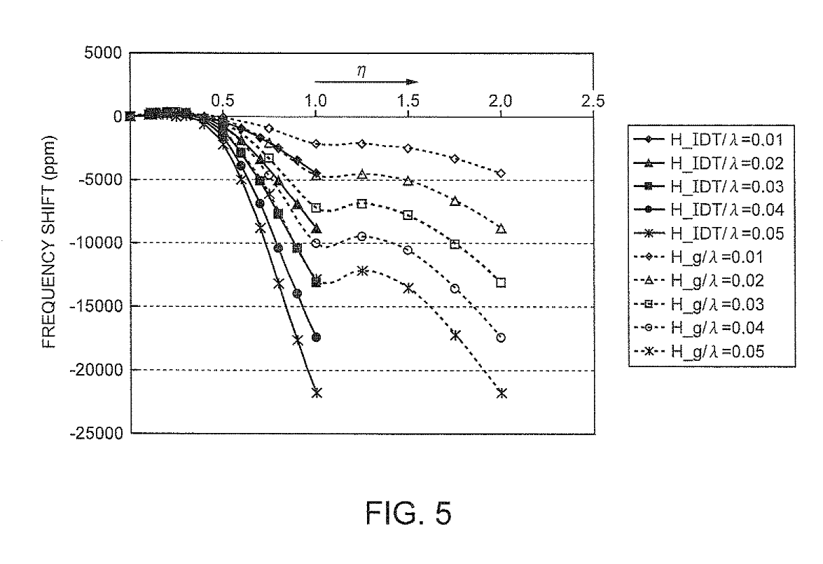

FIG. 5 is a graph showing the relationship between the electrode line width ratio η, normalized electrode thickness at each region of the electrode finger element, and the frequency shift (ppm). The horizontal axis represents the electrode line width ratio η, and the vertical axis represents the frequency shift, and the analysis result of the frequency shift in the range (indicated by the solid lines in the drawing) of H_IDT/λ from 0.01 to 0.05 and the range (indicated by the broken lines in the drawing) of H_g/λ from 0.01 to 0.05 is shown.

In the case in which the line width ratio η is equal to or higher than 0.3, and the normalized electrode thickness H_IDT/λ obtained by dividing the electrode thickness H_IDT in the apposition area of the electrode finger elements by the wavelength λ of the Lamb wave is larger than the electrode thickness H_g in the gap sections (expressed by the normalized electrode thickness H_g/λ) in FIG. 5, the relationship of ΔF_IDT/F<ΔF_g/F becomes true. In other words, the frequency (the phase velocity of the Lamb wave) in the gap sections becomes higher than the frequency (the phase velocity of the Lamb wave) in the apposition area.

By setting the frequency (the phase velocity of the Lamb wave) in the gap sections to be higher than the frequency (the phase velocity of the Lamb wave) in the apposition area as described above, the energy in the widthwise direction from the area of the gap sections can be trapped. Therefore, by appropriately setting H_IDT/λ, H_IDT, η_IDT, and η_g satisfying the relationship of ΔF_IDT/F<ΔF_g/F, it becomes possible to trap the energy in the widthwise direction.

It should be noted that the IDT electrode 20 and the reflectors 25, 26 are formed using a photolithographic process. In the photolithographic process, it is desirable to set the electrode width and the electrode thickness so as to prevent breaking, pattern omission, short circuit, and so on of the electrodes. Therefore, it is more preferable to set the dimensions in the ranges of 0.01≦H_IDT/λ≦0.05, 0.01≦H_g/λ≦0.05, 0.1≦η_IDT≦0.9, and 0.1≦η_g≦0.9.

Then, the Q-value as an important factor for evaluating the resonant characteristic of the Lamb-wave resonator will be explained.

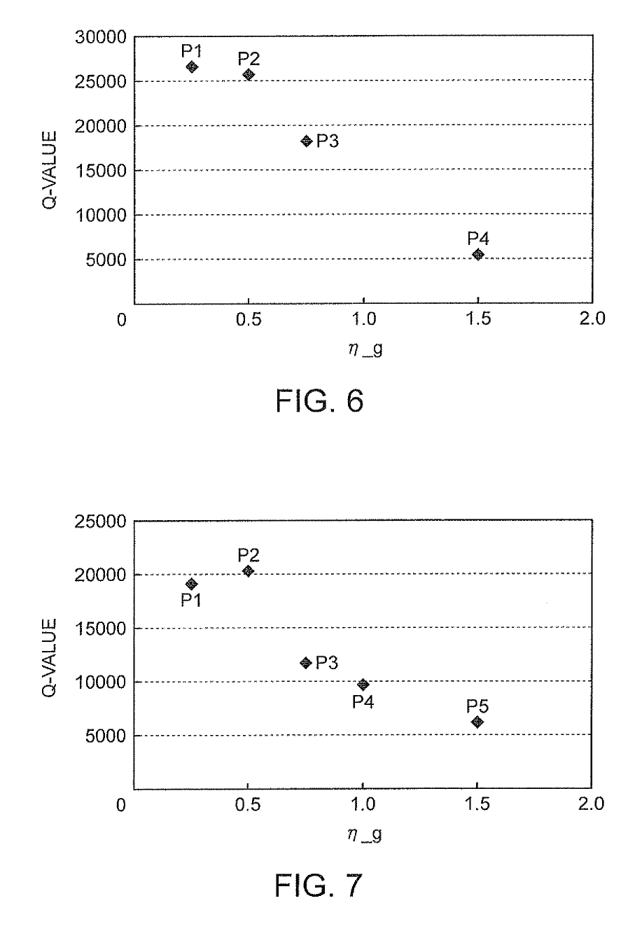

FIG. 6 is a graph showing a change in a Q-value corresponding to a change in a line width ratio η_g in the gap sections in the case in which the line width ratio η_IDT in the apposition area of the electrode finger elements is set to be 0.5.

According to FIG. 5, in the case in which η_IDT is set to be a constant value of 0.5, the relationship in the level of the frequency is reversed around the boundary point of 0.612 in η_g. Therefore, in FIG. 6, although in the range of η_g<0.612 in FIG. 6, deterioration in the Q-value does not occur because ΔF_IDT/F<ΔF_g/F is satisfied, in the range of η_g>0.612 in FIG. 6, the relationship is reversed to satisfy ΔF_IDT/F>ΔF_g/F, and therefore, the Q-value is deteriorated.

FIG. 7 is a graph showing a change in the Q-value corresponding to a change in the line width ratio η_g in the gap sections in the case in which the line width ratio η_IDT in the apposition area of the electrode finger elements is set to be 0.8. In FIG. 5, in the case in which η_IDT is set to be 0.8, the relationship in the level of the frequency is reversed around the boundary point of 1.514 in η_g.

However, although in the range of η_g<1.514, ΔF_IDT/F<ΔF_g/F is satisfied and therefore the deterioration in the Q-value ought to be little, the Q-value is substantially deteriorated in FIG. 7. This is caused by the fact that the magnitude of the frequency difference ΔF between ΔF_IDT/F and ΔF_g/F is involved therein.

For example, ΔF=2817 ppm corresponds to η_g=0.25, while ΔF=31 ppm, which is very small, corresponds to η_g=1.5. Therefore, it shows that even in the condition of ΔF_IDT/F<ΔF_g/F, the larger ΔF is, the more firmly the energy is trapped, and thus the high Q-value and the low crystal impedance (CI) can be achieved.

It should be noted that in FIG. 6, ΔF corresponding to the point P1 among the points (P1 through P4) representing the change in the Q-value corresponding to η_g satisfies ΔF=684 ppm.

Further, in FIG. 7, ΔF corresponding to the point P3 among the points (P1 through P5) representing the change in the Q-value corresponding to η_g satisfies ΔF=1599 ppm.

According to FIGS. 6 and 7, it is more preferable that ΔF_IDT/F<ΔF_g/F is satisfied, and the difference between ΔF_IDT/F and ΔF_g/F is equal to or larger than 684 ppm.

It should be noted that although in the present embodiment the quartz substrate with the Euler angles (0°, 42°, 0°) is used, this is not necessarily the limitation, but if the Euler angles (φ, θ, ψ) of the quartz substrate are selected in the ranges of −1°≦φ≦+1°, 35.0°≦θ≦47.2°, and −5°≦ψ≦+5°, substantially the same advantage can be obtained.

According to the present working example explained hereinabove, the phase velocity of the Lamb wave has a property of depending on the normalized substrate thickness (t/λ) of the quartz substrate 10, and if the normalized substrate thickness is made smaller, the phase velocity rises.

The Lamb-wave resonator has a plurality of modes, and the phase velocities in the respective modes aggregate in a range from 3000 (m/s) to 6000 (m/s), and in particular, densely aggregate in a range from 5000 (m/s) to 6000 (m/s), as the normalized substrate thickness t/λ increases.

It is conceivable that in the case in which the modes densely aggregate described as above, the mode coupling is apt to be caused, making it difficult to obtain a desired mode, or the phase velocity is apt to vary. Therefore, by setting the normalized substrate thickness of the quartz substrate 10 to satisfy 0<t/λ≦3, it becomes possible to eliminate the range in which the mode coupling is apt to occur.

Further, the relationship between the frequency variation ΔF_IDT/F in the apposition area and the frequency variation ΔF_g/F in the gap sections in the case of taking the frequency F corresponding to the condition of η_IDT=η_g=0 as a reference is set to be ΔF_IDT/F<ΔF_g/F. In other words, the phase velocity of the Lamb wave in the gap sections becomes higher than the phase velocity of the Lamb wave in the apposition area. Therefore, the displacement in the widthwise direction perpendicular to the propagation direction of the Lamb wave is converged in the areas outside the gap sections, thus the state with very little vibration leakage, namely the state in which the energy is trapped can be achieved.

As described above, by preventing the vibration leakage in the widthwise direction, it becomes possible to significantly reduce the amplitude of the reflected wave generated in the outer ends of the quartz substrate 10 in the widthwise direction, thereby reducing the spurious caused by the reflected waves from the outer ends of the quartz substrate 10 in the widthwise direction.

Further, by reducing the spurious caused by the reflected waves from the outer ends of the quartz substrate 10 in the widthwise direction, the drop of the Q-value as an important factor in evaluating the resonance characteristic of the Lamb-wave resonator and the increase in the CI value are prevented. Therefore, the oscillation of the Lamb-wave resonator can stably be maintained with the high Q-value, and the reduction of the power consumption can be realized with the low CI value.

Subsequently, a result obtained by the simulation of the relationships of a frequency temperature deviation (frequency temperature variation), the phase velocity, and the electromechanical coupling coefficient K² with respect to each of the phase velocity, the normalized substrate thickness t/λ, and the angle θ in the Euler angles (0°, θ, 0°) in the Lamb-wave resonator 1 (see FIGS. 2A, 2B, and 3) will be explained with reference to the drawings.

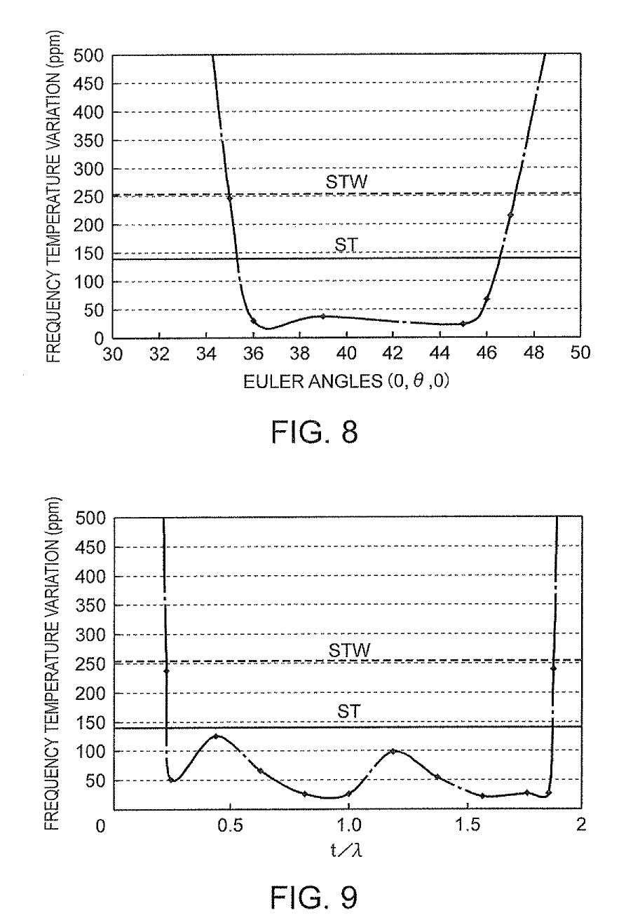

FIG. 8 is a graph showing a relationship between the frequency temperature variation (ppm) and the angle θ in the Euler angles (0°, θ, 0°). FIG. 8 shows that the Lamb-wave resonator 1 has a frequency temperature characteristic more preferable than that of an STW-cut quartz device in the range of the angle θ satisfying 35.0°≦θ≦47.2°.

It should be noted that the angle θ in the Euler angles more preferably satisfies 36°≦θ≦45° In the region of the angle θ, the frequency temperature variation becomes substantially flat, and the frequency temperature characteristic thereof becomes superior to that of an ST-cut quarts device.

FIG. 9 is a graph showing the relationship between the frequency temperature variation (ppm) and the normalized substrate thickness t/λ. As shown in FIG. 9, the frequency temperature characteristic superior to those of the STW-cut quartz device and the ST-cut quartz device is obtained in the range of the normalized substrate thickness t/λ satisfying 0.176≦t/λ≦1.925.

Then, the mutual relationships between the angle θ and the normalized substrate thickness t/λ and the phase velocity, frequency temperature variation, and the electromechanical coupling coefficient K² will be explained in detail.

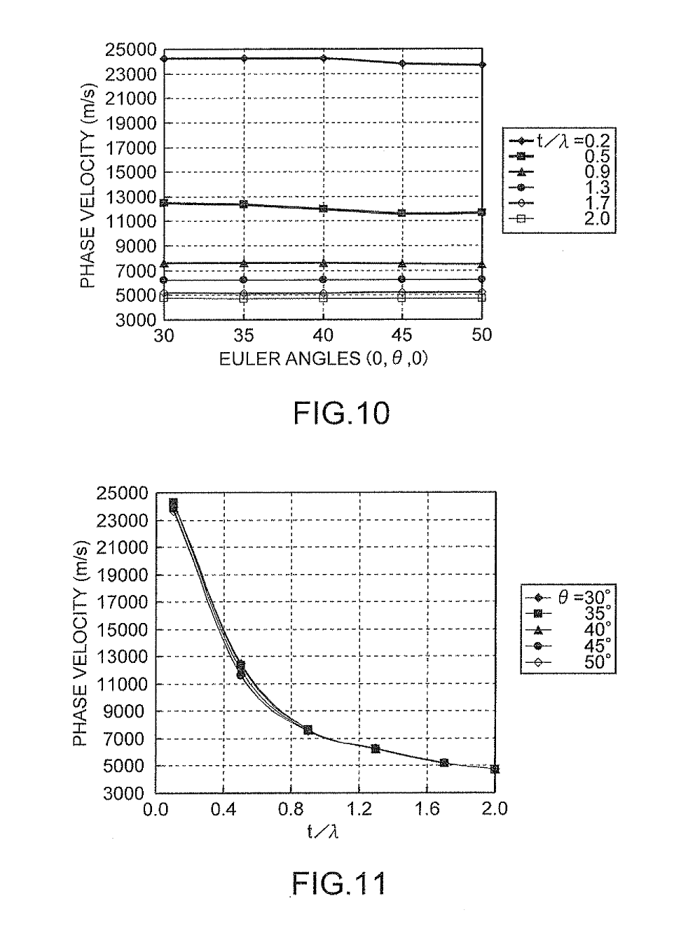

FIG. 10 is a graph showing a relationship between the angle θ in the Euler angles (0°, θ, 0°) and the phase velocity. Here, the normalized substrate thickness t/λ is set at 6 levels from 0.2 to 2.0, and the phase velocity corresponding to each of the levels of t/λ is plotted.

As shown in FIG. 10, in all cases except the case of the normalized substrate thickness t/λ2.0, the phase velocity equal to or higher than 5000 m/s can be obtained with the angle θ existing in the range of 30° through 50°.

FIG. 11 is a graph showing the relationship between the normalized substrate thickness t/λ and the phase velocity. The angle θ in the Euler angles (0°, θ, 0°) is set at 5 levels from 30° to 50°, and the phase velocity corresponding to each of the levels of the angle θ is plotted.

As shown in FIG. 11, the variation in the phase velocity is small between the values of the angle θ, and the phase velocity equal to or higher than 5000 m/s can be obtained in most of the range of the normalized substrate thickness t/λ from 0.2 to 2.

Then, the mutual relationships between the angle θ in the Euler angles (0°, θ, 0° and the normalized substrate thickness t/λ, and the phase velocity, the frequency temperature variation, and the electromechanical coupling coefficient K² will be explained.

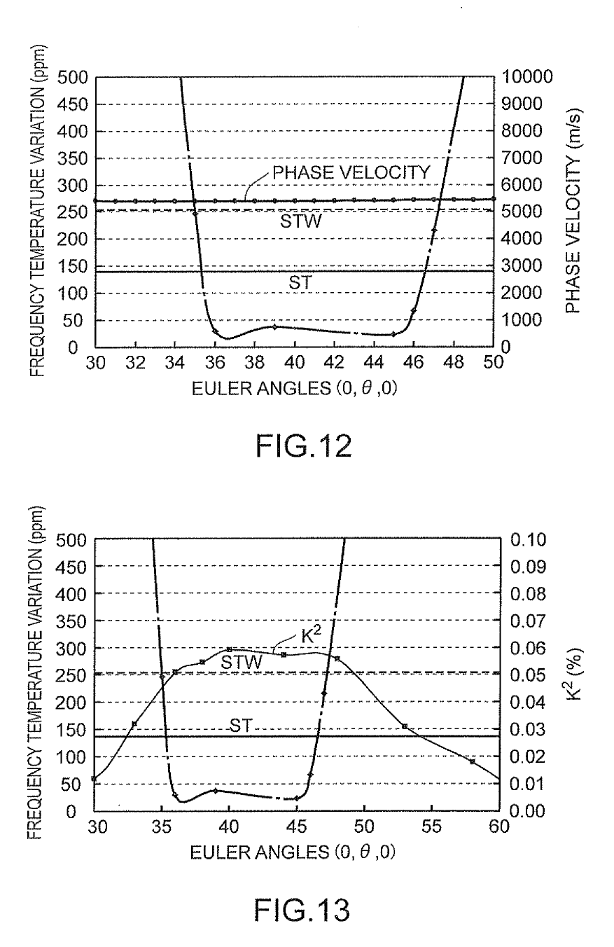

FIG. 12 is a graph showing the relationships between the angle θ, and the phase velocity and the frequency temperature variation. It should be noted that the normalized substrate thickness t/λ is assumed to be 1.7.

As shown in FIG. 12, it shows that the range of the angle θ in which the frequency temperature variation thereof is smaller than that of the STW-cut quartz device is 35°≦θ≦47.2° (see also FIG. 8), and that the phase velocity equal to or higher than 5000 m/s can be obtained in this range.

FIG. 13 is a graph showing relationships between the angle θ, and the electromechanical coupling coefficient K² and the frequency temperature variation. As shown in FIG. 13, the range of the angle θ in which the frequency temperature variation thereof is smaller than that of the STW-cut quartz device is 35°≦θ≦47.2° (see also FIG. 9).

In this range, the electromechanical coupling coefficient K² far exceeds 0.02, the value used as a reference. In the case of the range of the angle θ satisfying 32.5°≦θ≦47.2°, the electromechanical coupling coefficient K² becomes equal to or greater than 0.03, in the case of the range of the angle θ satisfying 34.2°≦θ≦47.2°, the electromechanical coupling coefficient K² becomes equal to or greater than 0.04, and in the case of the range of the angle θ satisfying 36°≦θ≦47.2°, the electromechanical coupling coefficient K² becomes equal to or greater than 0.05.

It should be noted that although in FIGS. 10, 12, and 13 the relationships between the respective characteristics while varying the angle θ with the angles φ and φ are set to be zero in the Euler angles (φ, θ, φ) are shown, it has been confirmed that substantially the same relationships are obtained in the ranges of −1°≦φ≦+1° and −5°≦ψ≦+5°.

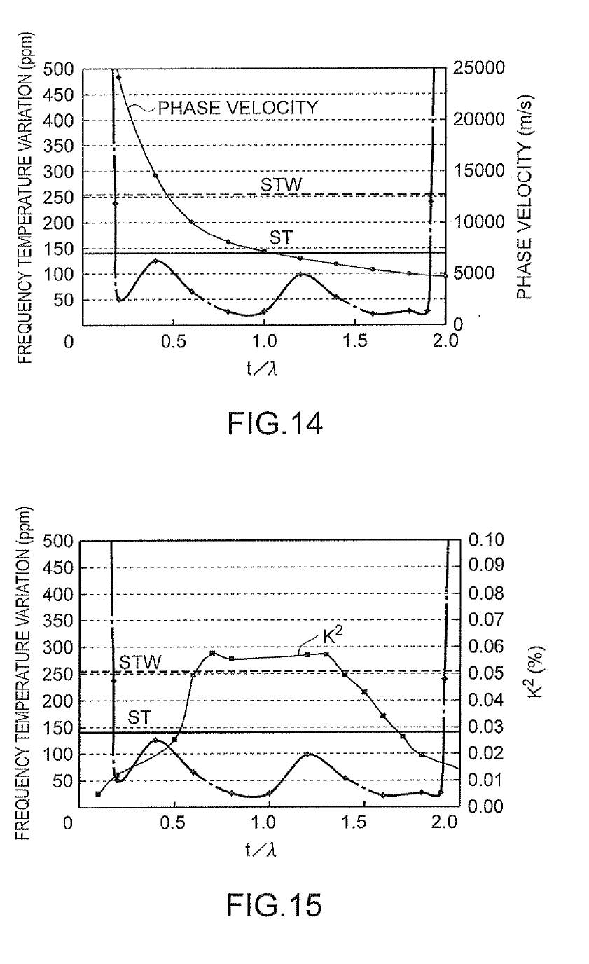

FIG. 14 is a graph showing the relationship between the normalized substrate thickness t/λ, and the phase velocity and the frequency temperature variation. As shown in FIG. 14, the range of the normalized substrate thickness t/λ, in which the frequency temperature variation thereof is smaller than that of the STW-cut quartz device, is 0.176≦t/λ≦1.925, and the phase velocity equal to or higher than 5000 m/s can be obtained in most of this range. In this range of the normalized substrate thickness t/λ, the smaller the normalized substrate thickness t/λ is, the faster the phase velocity becomes, and therefore, the high frequency band becomes available. In other words, by adjusting the normalized substrate thickness t/λ, the phase velocity can be adjusted.

FIG. 15 is a graph showing relationships between the normalized substrate thickness t/λ, and the electromechanical coupling coefficient K² and the frequency temperature variation. As shown in FIG. 15, the range of the normalized substrate thickness t/λ, in which the frequency temperature variation thereof is smaller than that of the STW-cut quartz device, is 0.176≦t/λ≦1.925, and the electromechanical coupling coefficient K² equal to or greater than 0.02 can be obtained in most of this range. In the range in which the normalized substrate thickness t/λ is close to 1, the area with the electromechanical coupling coefficient K² as high as equal to or greater than 0.05 can be obtained.

It should be noted that although in the present embodiment the explanations are presented while showing the case of using the quartz substrate as the piezoelectric substrate as an example, it is possible to use piezoelectric materials other than the quartz crystal as the substrate. For example, lithium tantalate, lithium niobate, lithium tetraborate, langasite, and potassium niobate can be employed. Further, a piezoelectric thin film made of zinc oxide, aluminum nitride, tantalum pentoxide or the like, a piezoelectric semiconductor made of cadmium sulfide, zinc sulfide, gallium arsenide, indium antimony or the like is also applicable.

However, a quartz substrate and other piezoelectric substrates have a significant difference in resonance characteristics, particularly in temperature characteristics. Therefore, if a quartz substrate is employed as a piezoelectric substrate, the frequency variation with respect to the temperature is suppressed to be smaller, and thus, preferable frequency temperature characteristics can be obtained. As described above, by using a quartz substrate as the piezoelectric substrate, and employing the optimum electrode design conditions described above, it becomes possible to provide a Lamb-wave resonator superior in the frequency temperature characteristics, and having a high Q-value, and a low C1 value.

Further, although in the present embodiment the Al electrodes are used as the IDT electrode 20 and the reflectors 25, 26, it is also possible to use an alloy consisting primarily of Al for these electrodes. If an Al alloy containing Au, Ag, Cu, Si, Ti, Pb, or the like equal to or smaller than 10% in terms of ratio by weight is used, a substantially the same advantage can be obtained.

### Example 2

Although in the Example 1 there is described an example of appropriately setting H_IDT/λ, H_g/λ, η_IDT, and η_g to satisfy the condition of ΔF_IDT/F<ΔF_g/F, in the Example 2, the density of the electrode finger elements in the apposition area and the density thereof in the gap sections are varied.

Although not shown in the drawings, the explanations therefor are presented with reference to FIGS. 4A and 4B. Here, the material of the electrode is selected so that a relationship between the density ρ_IDT of the electrode finger elements in the apposition area and the density ρ_g of the electrode finger elements in the gap sections in the IDT electrode 20 satisfies ρ_IDT>ρ_g.

Specifically, Cu, Ag, or Au or a metal consisting primarily thereof is used only in the apposition area (in the range indicated by the width Wi), and Al or a metal consisting primarily of Al is used in the gap sections (in the range indicated by the distance Wg).

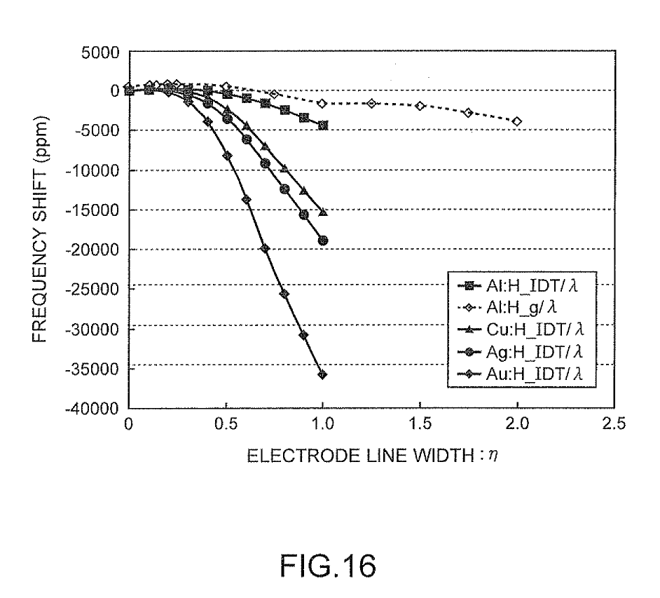

FIG. 16 is a graph showing a relationship between the electrode line width ratio η and the frequency variation (described as the frequency shift) in the case in which Al, Cu, Ag, or Au is used in the apposition area, and Al is used in the gap sections. It should be noted that FIG. 16 shows the case of H_IDT/λ=H_g/λ=0.01 as an example.

FIG. 16 shows that the higher the density in the apposition area is, the larger the frequency variation is. In other words, the frequency variation between the gap sections and the apposition area becomes larger. This means that the phase velocity of the Lamb wave in the gap sections becomes higher than the phase velocity thereof in the apposition area.

Therefore, the energy in the widthwise direction can be trapped similarly to the Example 1 described above by arranging the densities so as to satisfy ρ_IDT>ρ_g.

It should be noted that as a method of forming the IDT electrode 20 in the Example 2, there can be adopted a method of forming the apposition area, the gap sections, and the bus bar electrodes from Al, and then forming an electrodes made of Cu, Ag, or Au in the apposition section, or a method of forming the electrodes made of Cu, Ag, or Au in the apposition area and the electrodes made of Al in the gap sections separately. In the latter case, there is no need to particularly limit the material of the bus bar electrodes.

Further, the relationship between the electrode width of the apposition area and the electrode width of the gap sections can be η_g≦η_IDT and H_g/λ≦H_IDT/λ providing the relationship of ρ_IDT>ρ_g is satisfied.

### Example 3

Subsequently, Example 3 will be explained with reference to the drawings. In the Example 3, an insulating film is attached on a surface of the apposition area of the electrode finger elements.

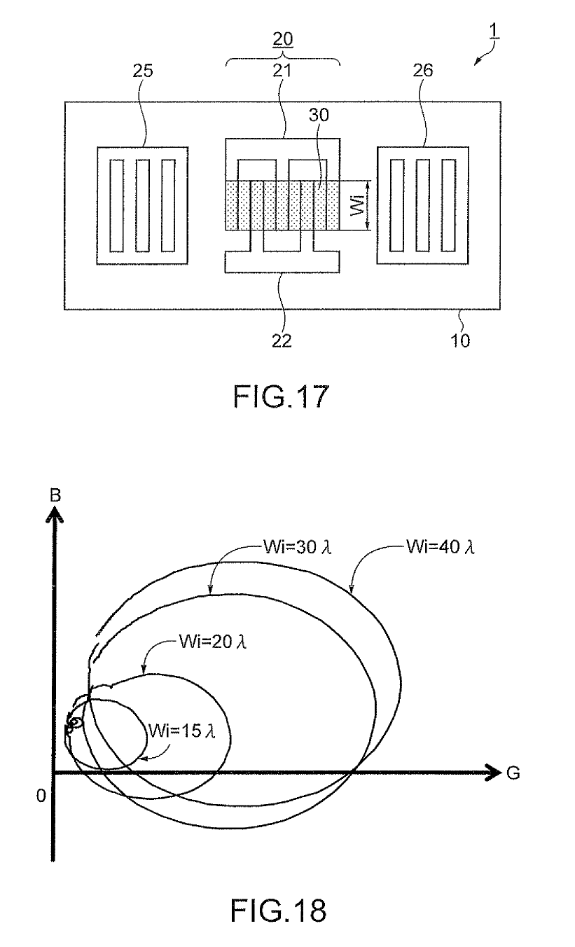

FIG. 17 is a plan view showing a schematic configuration of the Lamb-wave resonator according to the Example 3. In FIG. 17, on the surface of the apposition area (the area indicated by the width Wi) of the electrode finger elements, there is formed an insulating film 30.

As a material of the insulating film 30, SiO₂, Si, SiNₓ, Al₂O₃, ZnO, Ta₂O₅, and so on can be adopted. The SiO₂ film is often used as a film for correcting the temperature characteristic, and has a temperature characteristic improvement effect, and therefore, is more preferable.

Further, it is also possible to form the insulating film 30 only on the surface of the electrode finger elements in the apposition area, and thus, a failure of short circuit between the electrodes caused by a foreign matter such as dust can be solved.

As described above, the insulating film 30 described above is loaded on the apposition area to thereby make the mass addition effect in the apposition area more significant than the mass addition effect in the gap sections, thus an advantage substantially the same as in the case (the Example 2) in which ρ_IDT>ρ_g is satisfied even in the case in which the same electrode material is used throughout the entire IDT electrode 20.

It should be noted that the relationship between the electrode width of the apposition area and the electrode width of the gap sections can be η_g≦η_IDT and H_g/λ≦H_IDT/λ providing the insulating film 30 is loaded.

Further, by anodizing only the electrode finger elements in the apposition area, the advantage substantially the same as in the case of using a high-density metal can be obtained.

### Oscillator

Subsequently, an oscillator will be explained.

The oscillator is configured including the Lamb-wave resonator described above, and an oscillation circuit (not shown) for exciting the Lamb-wave resonator. As the Lamb-wave resonator, there is used one shown in any one of the Examples 1 through 3 described above.

Here, in each of the working examples in the range of the optimum electrode design conditions, the apposition width Wi of the electrode finger elements interdigitated to each other is in a range of 20λ through 40λ. The Lamb-wave resonator in the optimum electrode design conditions as described above can realize a high Q-value, and a low CI value. However, in the case in which the Lamb-wave resonator is attempted to be employed to an oscillator, the Lamb-wave resonator cannot be employed to the oscillator unless the oscillation conditions of the case of combining the Lamb-wave resonator with an oscillation circuit are satisfied.

In order to oscillate the Lamb-wave resonator, inductivity needs to be provided in the vicinity of a resonant frequency defined by the Lamb-wave resonator. For obtaining the inductivity in the vicinity of the resonant frequency, the apposition width Wi of the electrode finger elements interdigitated to each other is influential.

FIG. 18 shows a measurement result of an admittance circle diagram in the vicinity of the resonant frequency. In FIG. 18, when Wi is equal to or smaller than 15λ, the admittance B becomes to satisfy B>0 showing capacitive property, and therefore, oscillation does not occur.

Further, if the apposition width Wi of the electrode finger elements is equal to or larger than 20λ, the admittance B becomes to satisfy B<0 showing inductivity, and therefore, and therefore, the oscillation becomes possible when the Lamb-wave resonator and the oscillation circuit are assembled with each other.

Therefore, by employing the Lamb-wave resonator having the electrode finger elements interdigitated to each other with the apposition width Wi equal to or larger than 20λ, an oscillator having preferable oscillation characteristics can be realized.

The entire disclosure of Japanese Patent Application No. 2009-067545, filed Mar. 19, 2009 is expressly incorporated by reference herein.

What is claimed is:

1. A Lamb-wave resonator comprising:
a piezoelectric substrate;
an IDT electrode disposed on one principal surface of the piezoelectric substrate, having bus bar electrodes each connecting one ends of a plurality of electrode finger elements, the other ends of the plurality of electrode finger elements being interdigitated with each other to form an apposition area; and
a pair of reflectors disposed on the one principal surface of the piezoelectric substrate, and respectively arranged on both sides of the IDT electrode in a propagation direction of a Lamb wave,
wherein denoting a wavelength of the Lamb wave as λ, thickness t of the piezoelectric substrate satisfies 0<t/λ≦3, and
defining that a value obtained by dividing electrode finger line width of the IDT electrode by λ/2 as a line width ratio, the line width ratio of each of the electrode finger elements in the apposition area as η_IDT, normalized electrode thickness obtained by normalization with the wavelength λ as H_IDT/λ, the line width ratio of the electrode finger elements in gap sections as areas between ends of the apposition area in a direction perpendicular to the propagation direction of the Lamb wave and the bus bar electrodes as η_g, and a normalized electrode thickness obtained by normalization with the wavelength λ as H_g/λ,
each of H_IDT/λ, H_g/λ, η_IDT, and η_g is set so that a relationship between a frequency variation ΔF_IDT/F in the apposition area in a case of taking the frequency F with η_IDT=η_g=0 as a reference, and a frequency variation ΔF_g/F in the gap section satisfies ΔF_IDT/F<ΔF_g/F.

2. The Lamb-wave resonator according to claim 1, wherein the ΔF_IDT/F is set a following equation,
$$ΔF\_IDT / F = ( 9.31535 \times {10}^{8} \times {( H\_IDT / λ )}^{3} - 1.303219 \times {10}^{8} \times {( H\_IDT / λ )}^{2} + 1.707032 \times {10}^{6} \times ( H\_IDT / λ ) - 2.153813 \times {10}^{4} ) \times {η\_IDT}^{6} + ( - 2.265174 \times {10}^{9} \times {( H\_IDT / λ )}^{3} + 3.826626 \times {10}^{8} \times {( H\_IDT / λ )}^{2} - 5.666187 \times {10}^{6} \times ( H\_IDT / λ ) + 7.131896 \times {10}^{4} ) \times {η\_IDT}^{5} + ( 1.777402 \times {10}^{9} \times {( H\_IDT / λ )}^{3} - 4.02415 \times {10}^{8} \times {( H\_IDT / λ )}^{2} + 7.943602 \times {10}^{6} \times ( H\_IDT / λ ) - 9.161388 \times {10}^{4} ) \times {η\_IDT}^{4} + ( - 4.057486 \times {10}^{8} \times {( H\_IDT / λ )}^{3} + 1.792466 \times {10}^{8} \times {( H\_IDT / λ )}^{2} - 5.847306 \times {10}^{6} \times ( H\_IDT / λ ) + 5.720595 \times {10}^{4} ) \times {η\_IDT}^{3} + ( - 4.440021 \times {10}^{7} \times {( H\_IDT / λ )}^{3} - 2.971984 \times {10}^{7} \times {( H\_IDT / λ )}^{2} + 1.465112 \times {10}^{6} \times ( H\_IDT / λ ) - 1.766268 \times {10}^{4} ) \times {η\_IDT}^{2} + ( 5.803374 \times {10}^{6} \times {( H\_IDT / λ )}^{3} + 7.772027 \times {10}^{5} \times {( H\_IDT / λ )}^{2} - 4.721614 \times {10}^{4} \times ( H\_IDT / λ ) + 2.289947 \times {10}^{3} ) \times η\_IDT$$
in the case of satisfying the electrode line width ratio η≦1.0, the ΔF_g/F is set a following equation,
$$ΔF\_g / F = ( 2.30216 \times {10}^{8} \times {( H\_g / λ )}^{3} - 1.367095 \times {10}^{8} \times {( H\_g / λ )}^{2} + 3.659823 \times {10}^{6} \times ( H\_g / λ ) - 3.01777 \times {10}^{4} ) \times {η\_g}^{5} + ( - 5.380682 \times {10}^{9} \times {( H\_g / λ )}^{3} + 3.267274 \times {10}^{8} \times {( H\_g / λ )}^{2} - 8.220864 \times {10}^{6} \times ( H\_g / λ ) + 6.731244 \times {10}^{4} ) \times {η\_g}^{4} + ( 4.243229 \times {10}^{9} \times {( H\_g / λ )}^{3} - 2.672924 \times {10}^{8} \times {( H\_g / λ )}^{2} + 6.069945 \times {10}^{6} \times ( H\_g / λ ) - 4.768432 \times {10}^{4} ) \times {η\_g}^{3} + ( - 1.237277 \times {10}^{9} \times {( H\_g / λ )}^{3} + 8.270157 \times {10}^{7} \times {( H\_g / λ )}^{2} - 1.924936 \times {10}^{6} \times ( H\_g / λ ) + 9.760932 \times {10}^{3} ) \times {η\_g}^{2} + ( - 7.6659 \times {10}^{7} \times {( H\_g / λ )}^{3} - 6.447973 \times {10}^{6} \times {( H\_g / λ )}^{2} + 1.965583 \times {10}^{5} \times ( H\_g / λ ) + 9.0657 \times {10}^{2} ) \times η\_g$$
in the case of satisfying the electrode line width ratio η>1.0, the ΔF_g/F is set a following equation.
$$ΔF\_g / F = ( 9.77308 \times {10}^{7} \times {( H\_g / λ )}^{3} - 2.957309 \times {10}^{6} \times {( H\_g / λ )}^{2} + 3.402245 \times {10}^{5} \times ( H\_g / λ ) + 9.23408 \times {10}^{2} ) \times {η\_g}^{4} + ( - 5.997117 \times {10}^{8} \times {( H\_g / λ )}^{3} + 2.15036 \times {10}^{7} \times {( H\_g / λ )}^{2} - 2.052516 \times {10}^{6} \times ( H\_g / λ ) - 6.030188 \times {10}^{3} ) \times {η\_g}^{3} + ( 1.360087 \times {10}^{9} \times {( H\_g / λ )}^{3} - 5.537814 \times {10}^{7} \times {( H\_g / λ )}^{2} + 4.202198 \times {10}^{6} \times ( H\_g / λ ) + 1.459421 \times {10}^{4} ) \times {η\_g}^{2} + ( - 1.352976 \times {10}^{9} \times {( H\_g / λ )}^{3} + 6.122377 \times {10}^{7} \times {( H\_g / λ )}^{2} - 3.567924 \times {10}^{6} \times ( H\_g / λ ) - 1.553939 \times {10}^{4} ) \times η\_g + 4.989577 \times {10}^{8} \times {( H\_g / λ )}^{3} - 2.541272 \times {10}^{7} \times {( H\_g / λ )}^{2} + 8.585386 \times {10}^{5} \times ( H\_g / λ ) + 6.16996 \times {10}^{3}$$

3. The Lamb-wave resonator according to claim 1, wherein
the piezoelectric substrate is a quartz substrate having Euler angles (φ, κ, ψ) in ranges of −1°≦φ≦+1°, 35.0°≦θ≦47.2°, and −5°≦ψ≦+5°, and a relationship between the thickness t and the wavelength λ of the Lamb wave satisfying 0.176≦t/λ≦1.925.

4. The Lamb-wave resonator according to claim 1, wherein
a width of the apposition area of the electrode finger elements is one of equal to and larger than 20λ.

5. The Lamb-wave resonator according to claim 1, wherein
a relationship between a density ρ_IDT of the electrode finger elements in the apposition area and a density ρ_g of the electrode finger elements in the gap sections satisfies ρ_IDT>ρ_g.

6. The Lamb-wave resonator according to claim 1, further comprising:
a film having an insulating property disposed on a surface of the electrode finger elements in the apposition area.

7. An oscillator, comprising:
the Lamb-wave resonator according to claim 1; and
an oscillation circuit adapted to excite the Lamb-wave resonator.
